(19) United States
(12) Patent Application Publication
(10) Pub. No.: US 2026/0011631 A1
(43) Pub. Date: Jan. 8, 2026

(54) COMPOSITE COMPONENT

(71) Applicant: Murata Manufacturing Co., Ltd., Kyoto-fu (JP)

(72) Inventors: Yoshiaki SATAKE, Nagaokakyo-shi (JP); Tatsuya FUNAKI, Nagaokakyo-shi (JP)

(73) Assignee: Murata Manufacturing Co., Ltd., Kyoto-fu (JP)

(21) Appl. No.: 19/323,548

(22) Filed: Sep. 9, 2025

Related U.S. Application Data
(63) Continuation of application No. PCT/JP2024/022172, filed on Jun. 19, 2024.

(30) Foreign Application Priority Data
Jun. 26, 2023 (JP) 2023-103878

(51) Int. Cl. H01L 23/498; H01L 23/04; H01L 23/14; H01L 23/31; H01L 25/07

(52) U.S. Cl. CPC H01L 23/49827; H01L 23/04; H01L 23/147; H01L 23/3107; H01L 25/072

(57) ABSTRACT

A composite component containing one or more electronic components. The composite component includes a Si base layer having a first main surface, and a second main surface facing the first main surface, a redistribution layer disposed on the first main surface, a through-Si via extending through the Si base layer and the adhesive layer to electrically connect the redistribution layer and the electronic component, and extending through the Si base layer, an electronic component electrically connected to the through-Si via, and disposed on the second main surface, sidewall portions surrounding the electronic component, and disposed to form a recessed portion together with the Si base layer, and a resin sealing portion sealing the electronic component.

### CROSS-REFERENCE TO RELATED APPLICATIONS

This application claims benefit of priority to International Patent Application No. PCT/JP2024/022172, filed Jun. 19, 2024, and to Japanese Patent Application No. 2023-103878, filed Jun. 26, 2023, the entire contents of each are incorporated herein by reference.

### BACKGROUND

### Technical Field

The present disclosure relates to a composite component.

### Background Art

Conventionally, as a package in which a plurality of electronic components are combined, for example, there is an apparatus described in FIG. 4F of Japanese Patent Application Laid-Open No. 2019-125779. This apparatus (400F) includes a redistribution layer (306), a first mold layer (316) disposed on the redistribution layer (306), and a second mold layer (324) disposed on the first mold layer (316). Dies (318, 320) each sealed in the second mold layer (324) are connected to a bridge die (310) sealed in the first mold layer (316) with each of electrical connects (312) interposed between each die and the bridge, and are connected to the redistribution layer (306) with each of electrical connects (314) interposed between each die and the redistribution layer.

### SUMMARY

Meanwhile, the present inventor has found that, in the apparatus as described above, there is a possibility that cracking occurs and moisture enters from the outside, and the reliability of the apparatus may be degraded.

Thus, the present disclosure provides a composite component having superior reliability.

The present inventor has conducted intensive studies in view of the above, and has obtained the finding that cracking occurs because of the insufficient strength of the entire apparatus, and the large exposed areas of the first and second mold layers having relatively high hygroscopicity. Based on such technical finding, the present disclosure has been devised in which providing sidewall portions at opposite ends allows the strength of the entire apparatus to be increased and the first and second mold layers to be restrained from being exposed from the opposite ends. That is, the present disclosure includes the following embodiment.

According to an embodiment of the present disclosure, a composite component contains one or more electronic components. The composite component includes a Si base layer having a first main surface, and a second main surface facing the first main surface; a redistribution layer disposed on the first main surface; a through-Si via extending through the Si base layer and the adhesive layer to electrically connect the redistribution layer and the electronic component; an electronic component electrically connected to the through-Si via, and disposed on the second main surface; sidewall portions surrounding the electronic component, and disposed to form a recessed portion together with the Si base layer; and a resin sealing portion sealing the electronic component.

According to the above embodiment, the composite component includes the sidewall portions surrounding the electronic component and disposed to form the recessed portion together with the Si base layer. Hence, the strength of the entire composite component is improved. Moreover, since the sidewall portions are disposed at opposite ends of the composite component in sectional view, the resin sealing portion is not exposed at each of the opposite end surfaces of the composite component, which reduces the exposed area of the resin sealing portion. As a result, entry of moisture from the outside into the composite component is restrained. As described above, the composite component according to the present embodiment has superior reliability.

The composite component according to the embodiment of the present disclosure has superior reliability.

### BRIEF DESCRIPTION OF THE DRAWINGS

FIG. 1 is a plan view schematically illustrating a composite component according to a first embodiment;

FIG. 2 is a sectional view taken along line I-I in FIG. 1;

FIG. 3 is an enlarged view of a portion A in FIG. 2;

FIG. 4 is an enlarged view of a portion B in FIG. 2;

FIG. 5 is a sectional view illustrating a cavity in the composite component according to the first embodiment;

FIG. 6A is an explanatory view illustrating a method of manufacturing the composite component according to the first embodiment;

FIG. 6B is an explanatory view illustrating the method of manufacturing the composite component according to the first embodiment;

FIG. 6C is an explanatory view illustrating the method of manufacturing the composite component according to the first embodiment;

FIG. 6D is an explanatory view illustrating the method of manufacturing the composite component according to the first embodiment;

FIG. 6E is an explanatory view illustrating the method of manufacturing the composite component according to the first embodiment;

FIG. 6F is an explanatory view illustrating the method of manufacturing the composite component according to the first embodiment;

FIG. 6G is an explanatory view illustrating the method of manufacturing the composite component according to the first embodiment;

FIG. 6H is an explanatory view illustrating the method of manufacturing the composite component according to the first embodiment;

FIG. 6I is an explanatory view illustrating the method of manufacturing the composite component according to the first embodiment;

FIG. 6J is an explanatory view illustrating the method of manufacturing the composite component according to the first embodiment;

FIG. 6K is an explanatory view illustrating the method of manufacturing the composite component according to the first embodiment;

FIG. 6L is an explanatory view illustrating the method of manufacturing the composite component according to the first embodiment;

FIG. 6M is an explanatory view illustrating the method of manufacturing the composite component according to the first embodiment;

FIG. 6N is an explanatory view illustrating the method of manufacturing the composite component according to the first embodiment;

FIG. 7 is a sectional view schematically illustrating a composite component according to a second embodiment;

FIG. 8 is a sectional view illustrating a cavity in the composite component according to the second embodiment;

FIG. 9A is an explanatory view illustrating the method of manufacturing the composite component according to the first embodiment; and

FIG. 9B is an explanatory view illustrating the method of manufacturing the composite component according to the first embodiment.

### DETAILED DESCRIPTION

Hereinafter, a composite component according to one aspect of the present disclosure and a mounted structure thereof are described in detail with reference to the illustrated embodiments. Some schematic drawings are contained in the drawings and actual dimensions or ratios are not reflected in some cases. The dimensions (more specifically, the thickness and the like) of constituent elements in the composite component were measured based on scanning electron microscope (SEM) images taken with a SEM. The dimensions were each obtained from an average of the number of multiple measurements (number of measurements: n≥3).

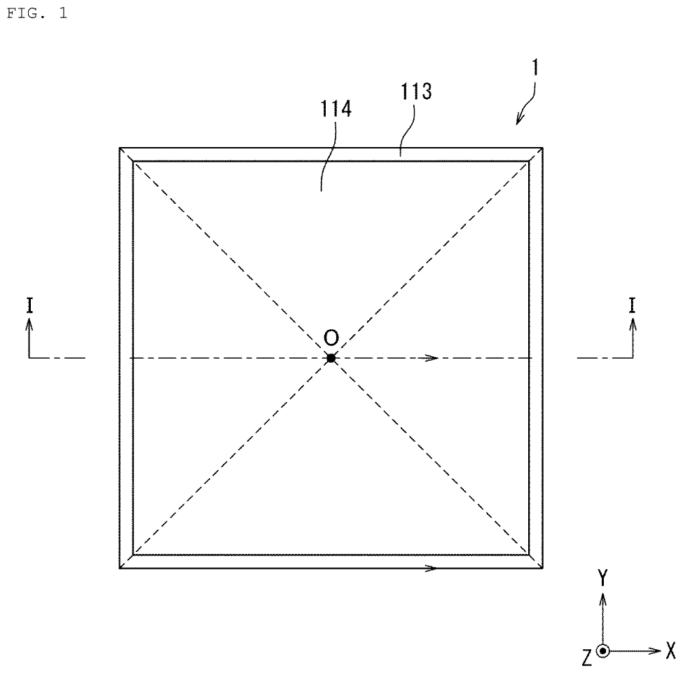

In the present specification, “on” attached immediately before the name of a member and indicating a disposed position of the member, does not simply mean an upper side in the vertical direction with respect to the member, but means that another member is disposed in contact with the member. For example, in FIG. 1, in a case that the vertical direction is parallel to a Z direction, the negative Z direction is a downward direction in the vertical direction, and the positive Z direction is an upward direction in the vertical direction, “a redistribution layer 120 is disposed on a first main surface 112a (of a Si base layer 112)” means that the redistribution layer 120 is disposed to be in contact with the first main surface 112a (lower-side surface). “An electronic component 111 is disposed on a second main surface 112b (of the Si base layer 112)” means that the electronic component 111 is disposed to be in contact with the second main surface 112b (upper-side surface).

### First Embodiment: Composite Component

A composite component according to a first embodiment contains one or more electronic components. In the present embodiment, as an example, a composite component containing two electronic components will be described.

According to the first embodiment, the composite component contains the two electronic components. The composite component includes a Si base layer having a first main surface, and a second main surface facing the first main surface; a redistribution layer disposed on the first main surface; through-Si vias electrically connected to the redistribution layer, and extending through the Si base layer and the adhesive layer; the electronic components each electrically connected to the through-Si vias, and disposed on the second main surface; sidewall portions surrounding each of the electronic components, and disposed to form a recessed portion together with the Si base layer; and resin sealing portions sealing each of the electronic components.

The composite component according to the first embodiment has superior reliability. The reason is presumed as follows.

The composite component according to the first embodiment includes the sidewall portions that surround the electronic components and that are disposed to form the recessed portion together with the Si base layer. Hence, the strength of the entire composite component is improved. Further, since the sidewall portions are disposed at opposite ends of the composite component in sectional view, the resin sealing portions are not exposed at the opposite end surfaces of the composite component, which reduces the exposed areas of the resin sealing portions. As a result, entry of moisture from the outside into the composite component is restrained. As described above, the composite component according to the present embodiment has superior reliability.

In addition, in a method of manufacturing the composite component, a mother integrated body in which a plurality of the composite components are coupled is used, and is cut at the sidewall portions disposed at the opposite ends of each of the composite components for singulation. Hence, as compared with a case of being cut at the resin sealing portions, unevenness due to, for example, falling off of a filler is less likely to occur on the cut surfaces to be formed, and the manufacturing efficiency of the composite components is improved.

### [Configuration of Composite Component]

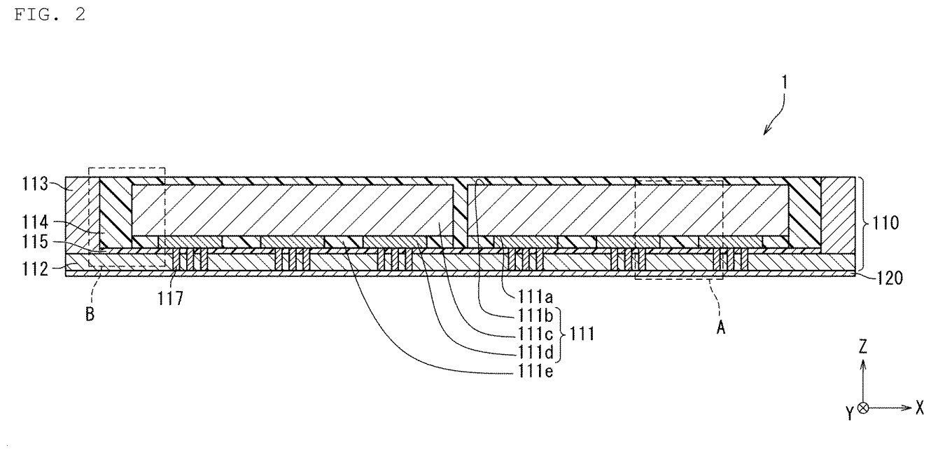

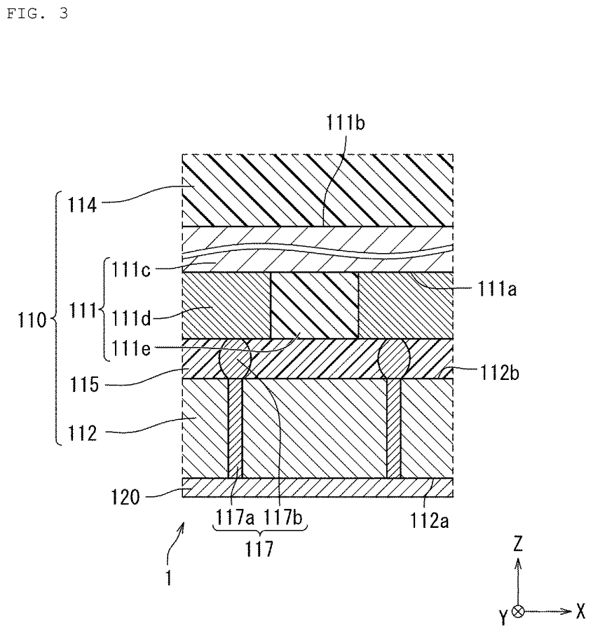

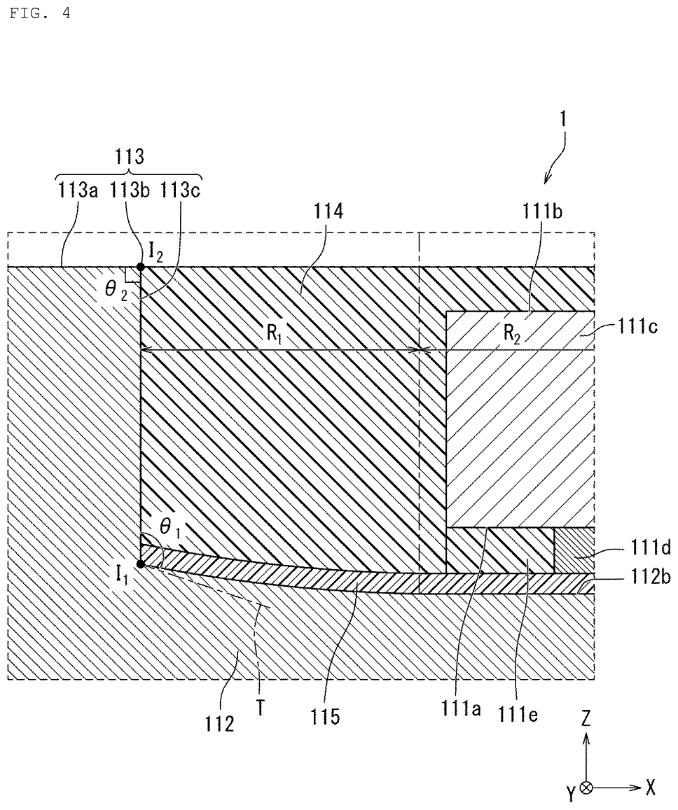

A configuration of the composite component according to the first embodiment will be described with reference to FIGS. 1, 2, 3, and 4. FIG. 1 is a plan view schematically illustrating the composite component according to the first embodiment of the present disclosure. FIG. 2 is a sectional view taken along line I-I in FIG. 1. FIG. 3 is an enlarged view of a portion A in FIG. 2. FIG. 4 is an enlarged view of a portion B in FIG. 2.

As illustrated in FIGS. 1 and 2, a composite component 1 according to the first embodiment has a substantially rectangular cuboid shape in which the adjacent surfaces are connected substantially perpendicularly. The composite component 1 contains two electronic components 111. In FIG. 2, a direction parallel to the thickness of the composite component 1 is designated as the Z direction, the positive Z direction is designated as the upper side, and the negative Z direction is designated as the lower side. In the section of the composite component 1 illustrated in FIG. 2, a direction perpendicular to the Z direction is designated as an X direction. A direction perpendicular to the section of the composite component 1 illustrated in FIG. 2 is designated as a Y direction.

The composite component 1 includes an electronic component layer 110, and a redistribution layer 120 bonded on a lower surface of the electronic component layer 110.

### (Electronic Component Layer)

The electronic component layer 110 adheres (is bonded) to the redistribution layer 120 on its lower surface. The electronic component layer 110 includes the two electronic components 111, a Si base layer 112, sidewall portions 113, resin sealing portions 114, an adhesive layer 115, and through-Si vias 117.

### —Electronic Component—

The two electronic components 111 are disposed inside the electronic component layer 110. The electronic components 111 are disposed on a second main surface 112b of the Si base layer 112. The electronic components 111 each include an electronic component body portion 111c having a first surface 111a and a second surface 111b that face each other, a plurality of component electrodes 111d that are disposed on the first surface 111a, and insulating portions 111e that are disposed between the plurality of component electrodes 111d. The electronic components 111 are supported by the Si base layer 112 with the adhesive layer 115 interposed therebetween. The electronic components 111 are sealed in the electronic component layer 110 by the resin sealing portions 114. The component electrodes 111d of each of the electronic components 111 are electrically connected to the redistribution layer 120 with the through-Si vias 117 interposed between the component electrodes and the redistribution layer. When a plurality of the electronic components 111 are present, their electronic components 111 may be of the same type or different types.

The two electronic components 111 are disposed inside the electronic component layer 110 such that their first surfaces 111a are located closer to the redistribution layer 120 side than their second surfaces 111b are. These two electronic components 111 are disposed in the same orientation and connected to the redistribution layer 120. As described above, the composite component 1 is simple in wiring, so that the manufacturing efficiency of the composite component is excellent.

The electronic components 111 are each, for example, an electronic component into which one or more elements are integrated in a substance similar to the substance constituting the Si base layer 112. The electronic components 111 are, for example, active components (more specifically, CPU, GPU, LSI, etc.) and passive components (more specifically, a capacitor, a resistor, an inductor, etc.).

The electronic component body portions 111c each include, for example, a ceramic or a semiconductor material (more specifically, silicon or the like).

The component electrodes 111d are each electrically connected to the redistribution layer 120 with only the through-Si vias 117 interposed between the component electrode and the redistribution layer. As described above, the via wiring for electrically connecting the component electrodes 111d to the redistribution layer 120 includes only the through-Si vias 117, and thus does not have (does not need) bumps (for example, solder bumps). Thus, the composite component 1 according to the present embodiment can further lower parasitic impedance due to the via wiring. This improves electrical characteristics of electronic equipment using the composite component 1. Further, since the wire lengths can be shortened as compared with conventional wiring, the thickness of the composite component 1 can be decreased, which makes it possible to make the composite component 1 smaller in size and height.

The component electrodes 111d each contain a conductive material, such as Cu, Ni, Sn, and Al, and an alloy containing them. Among these, the conductive material is preferably the same material as those of the through-Si vias 117. The thickness of each component electrode 111d is, for example, 1 μm to 30 μm, and preferably is 5 μm or less. The component electrodes 111d can each be thinned to a thickness of 1 to 5 μm. The thickness of each component electrode 111d can be, for example, ¼ to ⅙ times the thickness of each electronic component body portion 111c.

The insulating portions 111e each function as a layer for electrical insulation between the component electrodes 111d. The thickness of each insulating portion 111e is, for example, 1 to 30 μm, and preferably is 5 μm or less. The component electrodes 111d can each be thinned to a thickness of 1 to 5 μm. The thickness of each insulating portion 111e can be set to, for example, ¼ to ⅙ times the thickness of each electronic component body portion 111c. The thicknesses of the insulating portions 111e may be the same as those of the component electrodes 111d, and in such a case, the lower surfaces of the insulating portions 111e and the lower surfaces of the component electrodes 111d are flush with each other. When the lower surfaces of the insulating portions 111e and the lower surfaces of the component electrodes 111d are flush with each other, the thickness of the adhesive layer 115 can be reduced, which makes it possible to make the composite component 1 smaller in size and height.

### —Si Base Layer—

The Si base layer 112 has a first main surface 112a, and the second main surface 112b that faces the first main surface 112a. The Si base layer 112 supports the two electronic components 111 with the adhesive layer 115 interposed therebetween on the second main surface 112b, and is connected to the redistribution layer 120 on the first main surface 112a. The Si base layer 112 substantially includes Si.

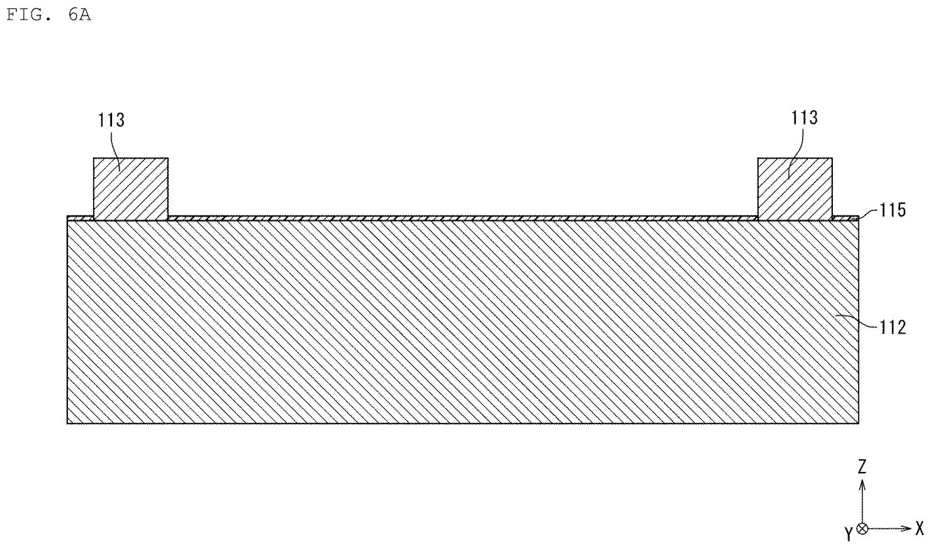

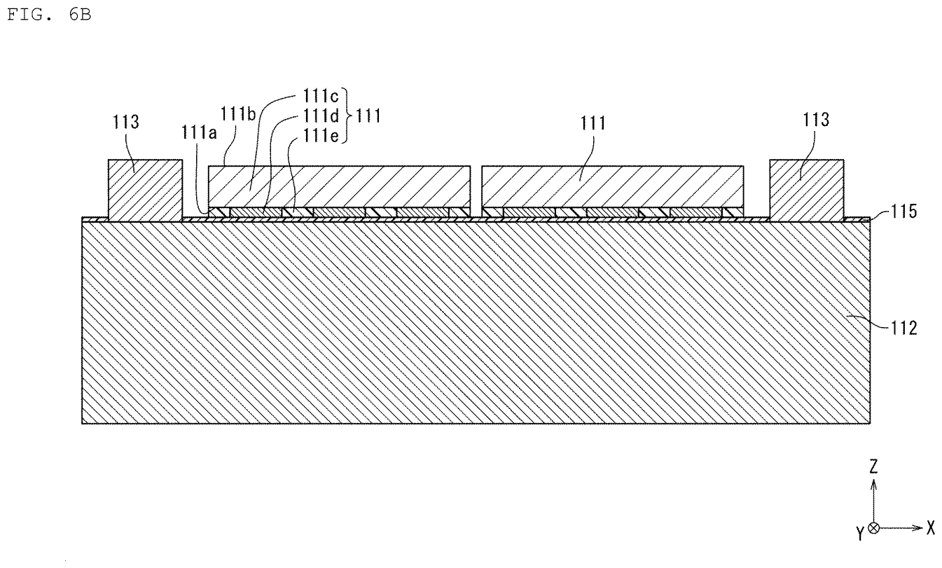

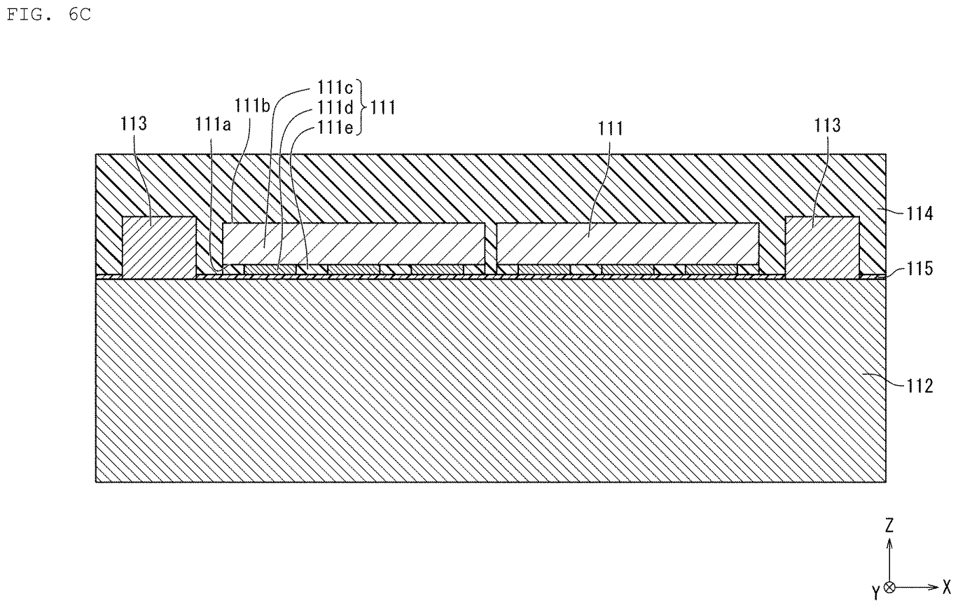

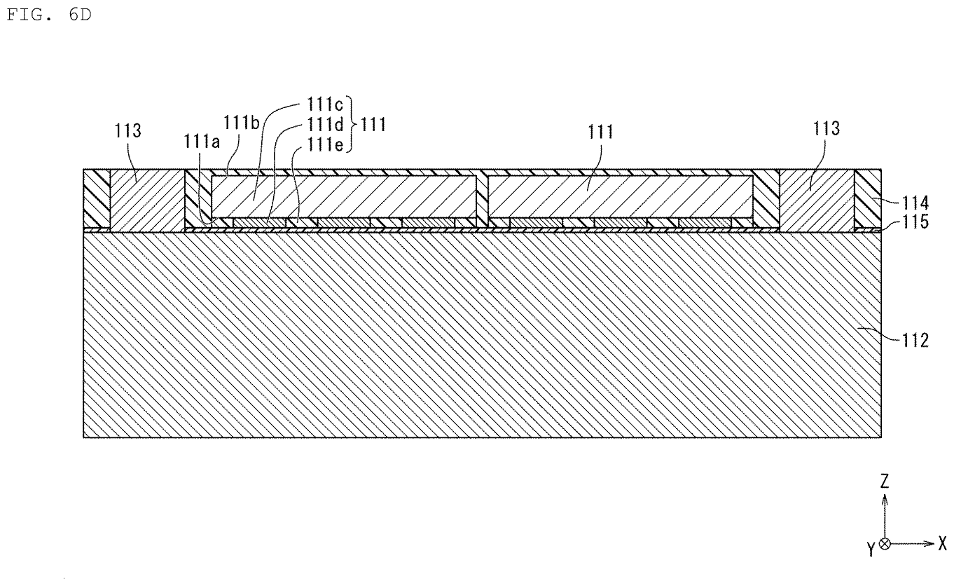

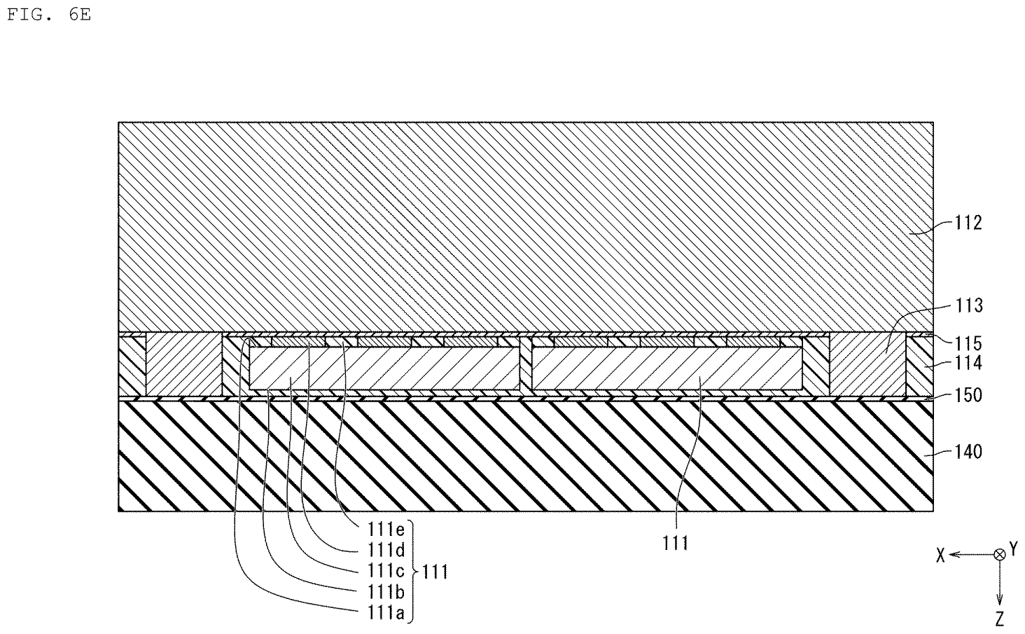

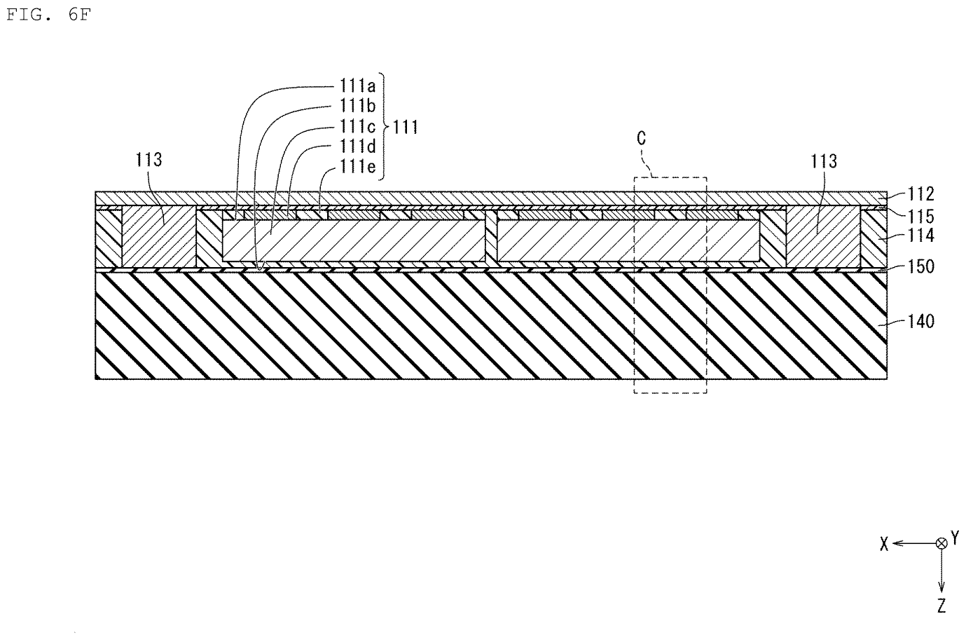

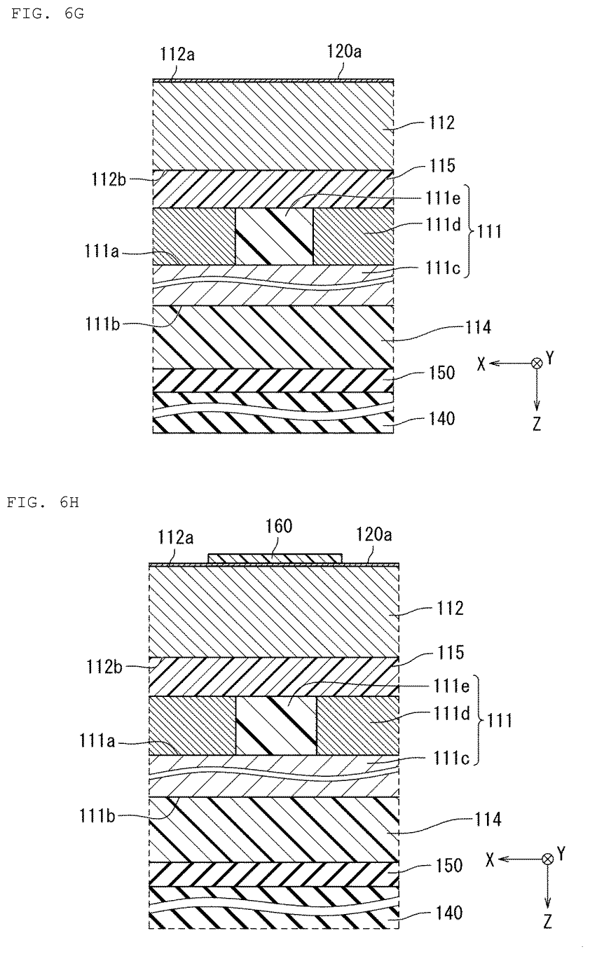

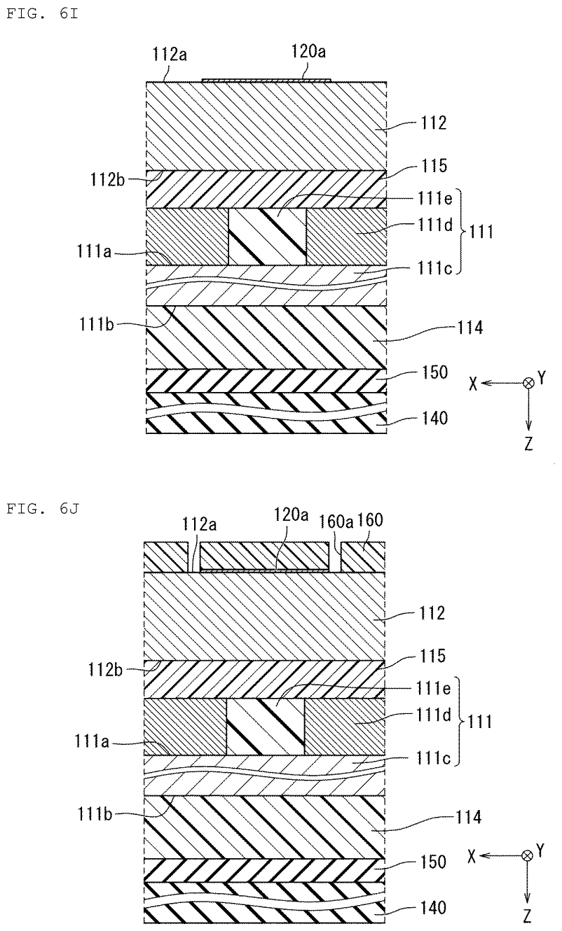

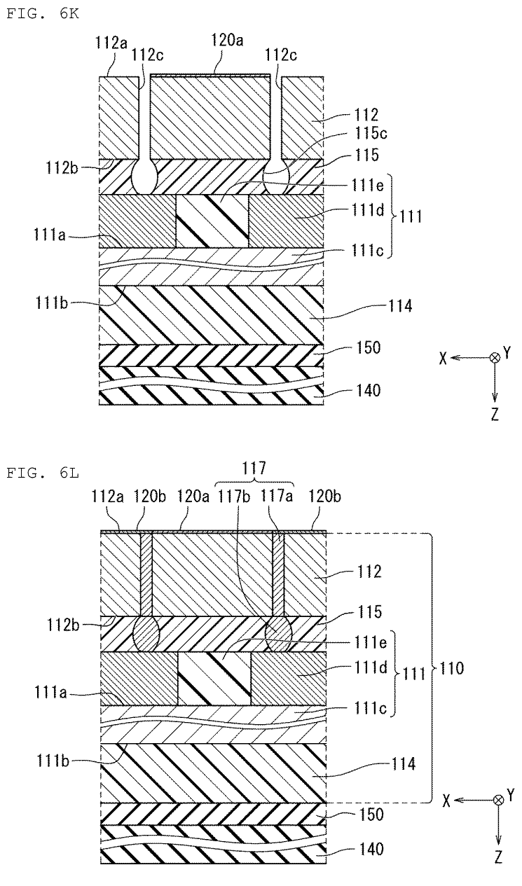

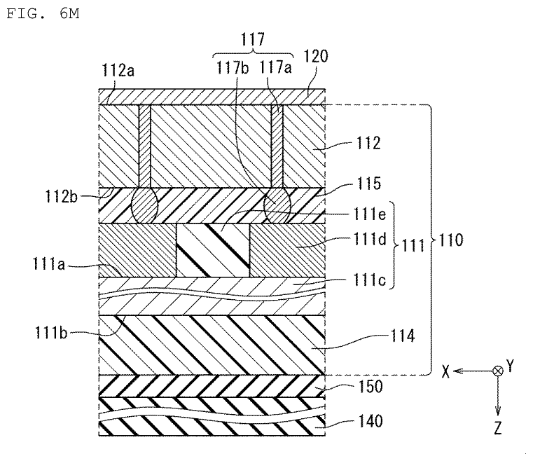

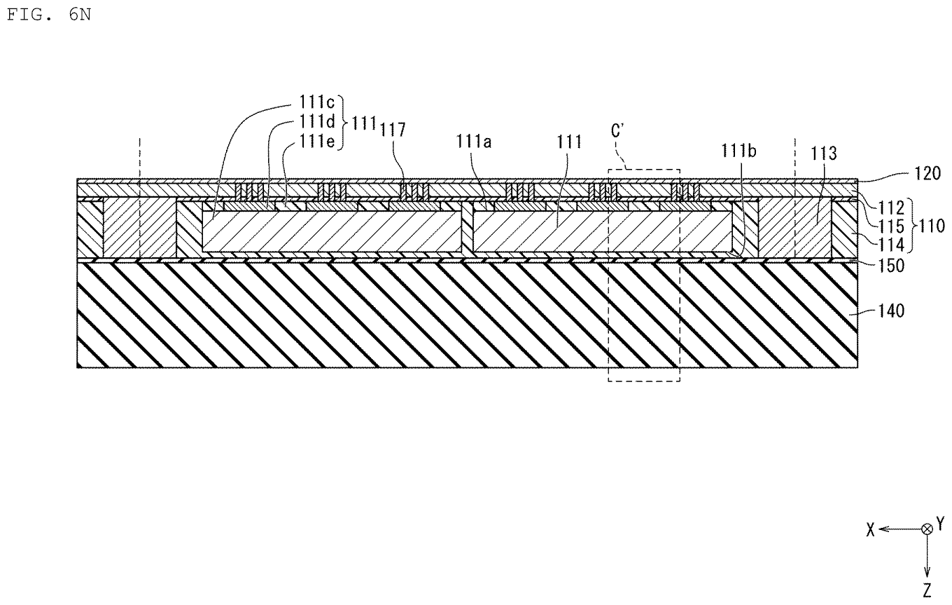

The thickness of the Si base layer 112 is, for example, 150 μm or less, preferably is 50 μm or less, and more preferably is 30 μm or less. The reason why the thickness of the Si base layer 112 can be extremely reduced as described above is that, in the method of manufacturing the composite component 1 to be described later, a Si support 140 is attached to the Si base layer 112 to reinforce the strength, and thus, if the Si base layer 112 is ground and thinned, breakage (cracking etc.) of the Si base layer 112 due to insufficient strength is less likely to occur (see FIG. 6F). The reinforcement of the strength by the Si support 140 makes it possible to manufacture the composite component 1. Since the thickness of the Si base layer 112 can be made extremely thinner than those of conventional layers, the via wiring (i.e., the through-Si vias 117) electrically connecting the component electrodes 111d of the two electronic components 111 to the redistribution layer 120, can be made shorter. This lowers the parasitic impedance due to the via wiring, which can improve electrical characteristics of electronic equipment using the composite component 1.

The second main surface 112b of the Si base layer 112 has the electronic components 111 mounted thereon. A region (mounting region), in the second main surface 112b, capable of mounting each electronic component 111 is a flat region R₂ of the second main surface 112b in the sectional view illustrated in FIG. 4. A region (region with mounting difficulty), in the second main surface 112b, in which it is difficult to mount each electronic component 111 is a curved region R₁ of the second main surface 112b in the cross-sectional view shown in FIG. 4. The curved region R₁ is a region from an inner-side surface 113c of each sidewall portion 113 to where the second main surface 112 becomes flat. The length of the curved region R₁ is preferably 100 μm or less, more preferably is 80 μm or less, further preferably is 60 μm or less, and particularly preferably is 50 μm or less, from the viewpoint of increasing the mounting area and enhancing integration.

### —Sidewall Portion—

The sidewall portions 113 are disposed on the second main surface 112b of the Si base layer 112 so as to surround the two electronic components 111. The sidewall portions 113 are disposed at end portions of the electronic component layer 110 so as to surround the two electronic components 111 in their entirety. The sidewall portions 113 are integrated with the Si base layer 112 in sectional view. This integration further improves the strength of the entire composite component 1. The thickness of each sidewall portion 113 is, for example, 90 to 130 μm. The sidewall portions 113 substantially include Si, for example.

As illustrated in FIG. 4, the inner-side surface 113c of each sidewall portion 113 and the second main surface 112b of the Si base layer 112 form an obtuse angle (more specifically, an angle greater than 90°). In the case that the inner-side surface 113c and the second main surface 112b form an obtuse angle, internal stress (which may occur during manufacture of the composite component 1 and during operation of the composite component 1) is less likely to concentrate, and cracking of the composite component 1 is less likely to occur. Thus, the reliability of the composite component 1 is further enhanced.

In the present specification, an angle θ₁ formed by the inner-side surface 113c and the second main surface 112b refers to an angle formed by the inner-side surface 113c being substantially linear and the second main surface 112b at a bend point (connection point, bonding point) I₁, seen in a ZX section at a magnification of 700× (SEM image taken at a magnification of 700× using a scanning electron microscope (“FlexSEM” manufactured by Hitachi High-Tech Corporation)). When the second main surface 112b is a curved surface, the angle θ₁ refers to an angle formed, at the bend point I₁ at which the inner-side surface 113c and the second main surface 112b are connected, by the substantially linear inner-side surface 113c and a tangent T that is in contact with the bend point I₁. The ZX section of the composite component 1 for determining an obtuse angle includes a point O at which diagonals (broken lines in FIG. 1) intersect in the composite component 1 substantially rectangular in plan view in FIG. 1, and is formed by cutting the composite component 1 along a plane (I-I cross section in FIG. 1) parallel to a side surface of the composite component 1.

The angle θ₁ formed by the inner-side surface 113c and the second main surface 112b is preferably 100° or more, more preferably is 120° or more, and further preferably is 130° or more, from the viewpoint of reducing local concentration of the internal stress and restraining the occurrence of the cracking in the composite component 1.

The angle θ₁ formed by the inner-side surface 113c and the second main surface 112b can be achieved by nonuniformly supplying an etching gas to an etching target, as described in detail in the method of manufacturing the composite component to be described later.

The angle θ₁ formed by the inner-side surface 113c and the second main surface 112b is preferably 130° or less, more preferably is 120° or less, and further preferably is 100° or less, from the viewpoint of increasing the mountable region on the second main surface 112b for the electronic components 111.

The ratio of the width between the inner-side surfaces 113c facing each other across the recessed portion to the width of each sidewall portion 113 is 10 to 1000. When this width ratio is 10 or more, the proportion occupied by each sidewall portion 113 is at or above a certain level, so that the rigidity of the composite component 1 is increased. Furthermore, when the width ratio is 1000 or less, the area (mounting area) in which the electronic components 111 can be mounted is at or above a certain amount, so that further integration is possible.

The width of each sidewall portion 113 is a length between the inner-side surface 113c and the outer-side surface of the sidewall portion 113, the length including the point O at which the diagonals (broken lines in FIG. 1) intersect in plan view illustrated in FIG. 1, extending along the straight line (alternate long and short dash line in FIG. 1) parallel to the side surface of the composite component 1. The width between the inner-side surfaces 113c facing each other across the recessed portion is a length between one of the inner-side surfaces 113c and the other inner-side surface 113c facing the one inner-side surface 113c, the length including the point O at which the diagonals (broken lines in FIG. 1) intersect in plan view illustrated in FIG. 1, extending along the straight line (alternate long and short dash line in FIG. 1) parallel to the side surface of the composite component 1.

### —Resin Sealing Portion—

The resin sealing portions 114 seal the two electronic components 111.

The resin sealing portions 114 each contain, for example, a resin (more specifically, an epoxy resin etc.) and a filler (more specifically, silica filler etc.), and allow the two electronic components 111 to be integrated with a resin. The two electronic components 111 can be integrated with the resin, and thus, if the two electronic components 111 have different dimensions and shapes from each other, the two electronic components 111 can be disposed inside the electronic component layer 110. This enables design with a high degree of freedom, and the two or more electronic components 111 can be combined according to applications. For example, the composite component 1 can contain different types of the electronic components 111.

### —Adhesive Layer—

The adhesive layer 115 adheres the two electronic components 111 to the second main surface 112b of the Si base layer 112. In the present specification, the thickness of the adhesive layer 115 refers to a thickness in the Z direction from the lower surfaces of the component electrodes 111d to the second main surface 112b of the Si base layer 112. The thickness of the adhesive layer 115 is, for example, 4 to 6 μm.

### —Through-Si Via—

The through-Si vias 117 extend through the Si base layer 112 (and the adhesive layer 115) to electrically connect the component electrodes 111d and the redistribution layer 120.

Each of the through-Si vias 117 includes a through-Si via body portion 117a and an extending portion 117b. The through-Si via body portions 117a are electrically connected to the redistribution layer 120 and extend through the Si base layer 112. The extending portions 117b are electrically connected to the through-Si via body portions 117a, extend from the second main surface 112b of the Si base layer 112, extend through the adhesive layer 115, and are electrically connected to the component electrodes 111d. As described above, the via wiring for electrically connecting the component electrodes 111d to the redistribution layer 120 includes only the through-Si vias 117, and thus does not have (does not need) bumps (for example, solder bumps). Thus, the composite component 1 according to the present embodiment can further lower parasitic impedance due to the via wiring. This improves electrical characteristics of electronic equipment using the composite component 1. Further, since the wire lengths can be shortened as compared with conventional wiring, the thickness of the composite component 1 can be decreased, which makes it possible to make the composite component 1 smaller in size and height. The length of the via wire (i.e., the length of the through-Si via 117 in the laminating direction) is, for example, 3 μm to 36 μm. When an (XY) sectional shape of each through-Si via 117 is a substantially circular shape, the (XY) sectional diameter (diameter) is, for example, 1 to 20 μm.

In FIG. 2, the through-Si vias 117 are substantially linear in the laminating direction. The sectional shape of each through-Si via 117 in the ZX plane is substantially rectangular in FIG. 2. Examples of the (XY) sectional shape of each through-Si via 117 on the XY plane include a substantially circular shape, a substantially polygonal shape, and a shape in which corners of the substantially polygonal shape are rounded. Seed layers and barrier layers may be provided between the through-Si vias 117, and between the resin sealing portion 114 and the adhesive layer 115.

### (Redistribution Layer)

The redistribution layer 120 is disposed on the first main surface 112a of the Si base layer 112. The redistribution layer 120 is a multilayer wiring layer (sheet or substrate made therefrom). The redistribution layer 120 includes wiring (conductive wiring) 120b and a dielectric film 120a that substantially includes an inorganic material (inorganic insulating material). While the dielectric film 120a and the wiring 120b are not illustrated in the redistribution layer 120 in FIG. 3, the redistribution layer 120 is configured by laminating a plurality of the dielectric films 120a and a plurality of pieces of the wiring 120b. For example, the plurality of dielectric films 120a and the plurality of pieces of wiring 120b in FIG. 6L to be described later are laminated to constitute the redistribution layer 120 in FIG. 6M to be described later.

The wiring 120b includes a conductive via. The conductive via electrically connects wires between different layers in the redistribution layer 120. The wiring 120b includes a conductive material. The conductive material is, for example, Cu, Ag, and Au, and an alloy containing them, and among them, Cu is preferable. The redistribution layer 120 is allowed to include a plurality of layers, and includes, for example, two or more layers of the wiring 120b and one or more layers of the dielectric film 120a. The thickness of the redistribution layer 120 is a value (in μm) obtained by multiplying the thickness of one layer of the wiring 120b and the dielectric film 120a that constitute the redistribution layer 120 by the total number of layers in the redistribution layer 120. Note that the thickness of the wiring 120b in the one layer does not include the thickness of the conductive via.

The dielectric film 120a includes an inorganic insulating material as an insulating material. Examples of the inorganic insulating material include silicon oxide (SiO₂), silicon nitride (SiN and Si₃N₄), and silicon carbon nitride (SiCN). When the dielectric film 120a includes the inorganic insulating material, the wiring width can be made about 1/10 as compared with a dielectric film including an organic insulating material. This makes it possible to make the composite component 1 further smaller in size and height.

The dielectric film 120a may be a multi-component film containing two or more components. The multi-component film may be a multilayer film in which multiple layers are formed for each component.

### [Method of Manufacturing Composite Component]

An example of the method of manufacturing the composite component 1 according to the first embodiment will be described.

The method of manufacturing the composite component 1 may include, for example, a cavity forming step of forming a recessed cavity having a Si base layer, and lattice-shaped sidewall portions disposed on the Si base layer; an electronic component adhering step of adhering one or more electronic components to a bottom surface of the cavity; an electronic component sealing step of sealing the one or more electronic components with a resin to form resin sealing portions; a Si base layer thinning step of thinning the Si base layer; a through-hole forming step of forming through-holes in the thinned Si base layer to expose a part of each of the electronic components; a through-Si via forming step of forming a through-Si via in the through-holes; and a redistribution layer forming step of forming a redistribution layer.

The method of manufacturing the composite component 1 may further include an insulating portion forming step of forming insulating portions each between component electrodes of each of the electronic components; a resin sealing portion thinning step of thinning the resin sealing portions; a Si support attaching step of attaching a Si support to the resin sealing portions; a dielectric film forming step of forming a dielectric film having a predetermined pattern on the Si base layer; an operation checking step of checking an operation of the composite component; and a cutting step of cutting the composite component with a dicing machine for singulation.

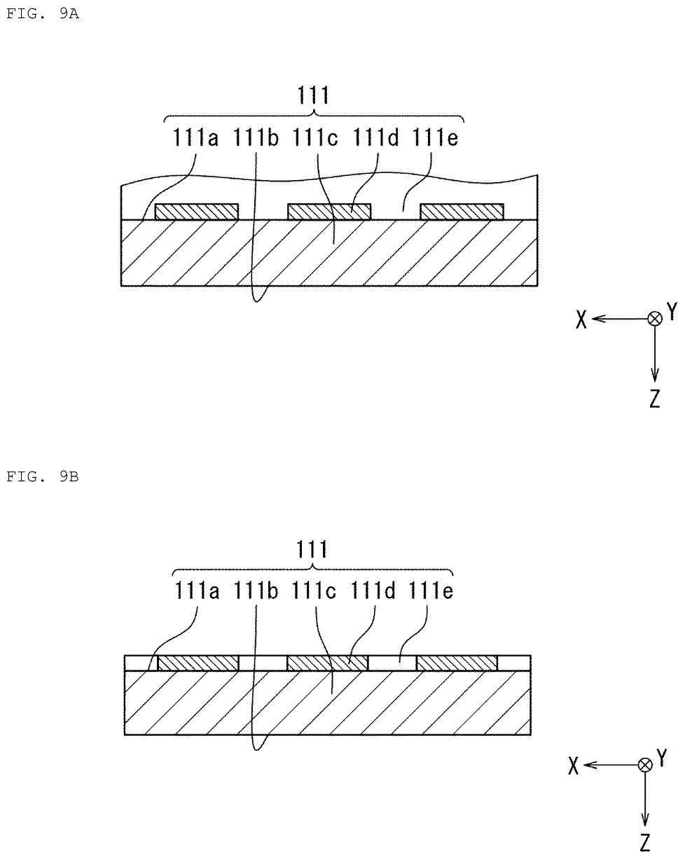

An example of the method of manufacturing the composite component 1 will be specifically described with reference to FIGS. 9A and 9B, and FIGS. 6A to 6N. FIGS. 9A and 9B, and FIGS. 6A to 6N are views for explaining the method of manufacturing the composite component 1. The method of manufacturing the composite component 1 according to the first embodiment is composed of the insulating portion forming step, the cavity forming step, the electronic component adhering step, the electronic component sealing step, the resin sealing portion thinning step, the Si support attaching step, the Si base layer thinning step, the dielectric film forming step, the through-hole forming step, the through-Si via forming step, the redistribution layer forming step, the operation checking step, and the cutting step. In this manufacturing method, a mother integrated body in which the composite components 1 are integrated is manufactured from the cavity forming step to the operation checking step.

### (Insulating Portion Forming Step)

In the insulating portion forming step, the insulating portions 111e are each formed between the component electrodes 111d of each electronic component 111. Specifically, in the insulating portion forming step, a coating film containing a resin is formed, and is subjected to planarization processing to form the insulating portions 111e. A solution containing a resin and a solvent is applied using a spin coating method to form the coating film. Here, the lowest portion of the coating film is made higher than the highest portions of the component electrodes 111d. That is, the coating film is formed such that all of the plurality of component electrodes 111d are fully buried under the coating film. As illustrated in FIG. 9A, the coating layer is dried to form the insulating portions 111e. The insulating portions 111e before being subjected to the subsequent planarization processing preferably fully cover the component electrodes 111d.

In the planarization processing, as illustrated in FIG. 9B, surfaces of the component electrodes 111d and the insulating portions 111e are ground and planarized using, for example, a surface planer, a chemical mechanical polisher (CMP), and a grinder, and the insulating portions 111e are each formed between the component electrodes 111d. As a result, the top surfaces of the component electrodes 111d are exposed, and the top surfaces of the component electrodes 111d and the insulating portions 111e become flush with each other.

### (Cavity Forming Step)

In the cavity forming step, a recessed cavity having the Si base layer 112, and the lattice-shaped sidewall portions 113 disposed on the Si base layer 112, are formed. Specifically, a Si wafer is prepared first in the cavity forming step. A mask covering portions corresponding to the sidewall portions 113 in plan view is formed on a main surface of the Si wafer. Dry etching (more specifically, reactive ion etching (RIE), sputter etching, etc.) is performed in this state, and then, the mask is removed. As a result, the recessed cavity is formed as illustrated in FIG. 6A, the recessed cavity having the Si base layer 112, a substantially rectangular (in plan view) bottom surface disposed on the Si base layer 112, and the sidewall portions 113 disposed in a lattice shape so as to surround the substantially rectangular bottom surface. Since the recessed cavity is formed by removing a part of the Si wafer by etching, the sidewall portions 113 and the Si base layer 112 are integrated. The depth (length in the Z direction from an upper surface of the resin sealing portion 114 flush with the sidewall portion 113 to the second main surface 112b of the Si base layer 112) of the cavity is, for example, 200 μm, which is equal to or greater than the thickness of the electronic component 111.

An aspect in which the inner-side surface 113c of the sidewall portion 113 and the second main surface 112b (bottom surface) of the Si base layer 112 form an obtuse angle at the bend point I₁, can be accomplished by employing a dry etching method and supplying an etching gas nonuniformly to an etching target (Si wafer). The phrase “supplying the etching gas nonuniformly” means here that the amount of supply of the etching gas to the vicinity of the boundary between the mask and an opening of the mask is made smaller than the amount of supply of the etching gas to the opening other than the vicinity of the boundary. Such nonuniform supply of the etching gas can be controlled by, for example, setting pressure of the etching gas to be higher than pressure of the etching gas in normal use.

The shape of the Si wafer may be a flat cylindrical shape when viewed from above in plan view, but is not limited thereto. When the shape of the Si wafer is a flat cylindrical shape, the thickness of the Si wafer is, for example, 775 μm (diameter φ of Si wafer of 300 mm), 725 μm (φ200 mm), 675 μm (150 mm), or 525 μm (φ100 mm). The cavity forming step may be performed before the insulating portion forming step. Both the Si base layer 112 and the sidewall portion 113 substantially include Si. The term “flat” means that the ratio (aspect ratio) of the height to the diameter of the circle in the cylindrical shape is small.

### Example

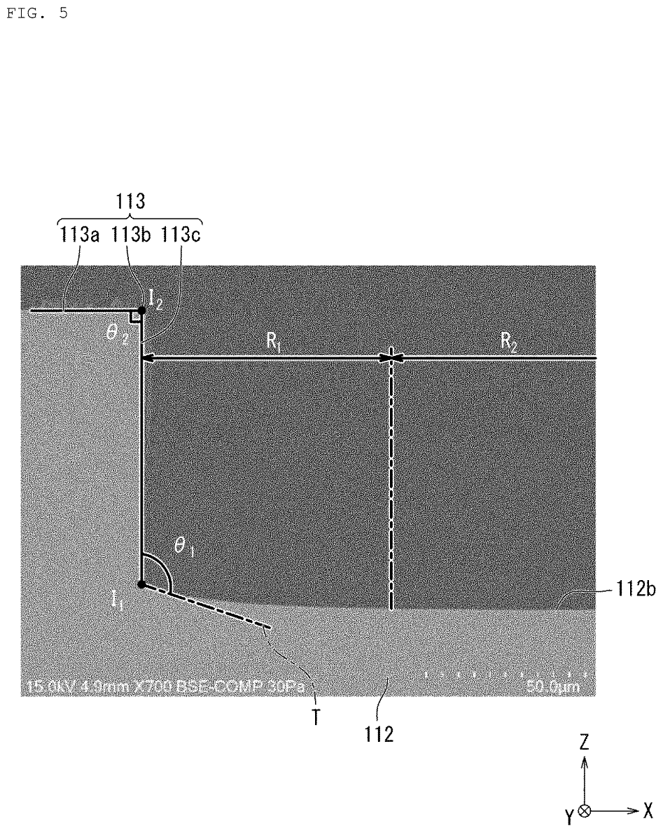

FIG. 5 is a sectional view illustrating the cavity (obtained by integrating the sidewall portion 113 and the Si base layer 112) formed in the cavity forming step of the method of manufacturing the composite component 1. FIG. 5 is a scanning electron microscope image (SEM image taken at a magnification of 700× using a scanning electron microscope (“FlexSEM” manufactured by Hitachi High-Tech Corporation)) of a cut surface of the cavity. This cut surface included a point at which the diagonals of the bottom surface, of the cavity, having a substantially rectangular shape in plan view intersect, and was formed by being cut along a plane parallel to a surface to be cut in the cutting step. As illustrated in FIG. 5, the angle θ₁ formed by the inner-side surface 113c of the sidewall portion 113 and the tangent T of the second main surface 112b at the bend point I₁ of the inner-side surface 113c and the second main surface 112b of the Si base layer 112, was an obtuse angle. An angle formed by the inner-side surface 113c of the sidewall portion 113 and an upper surface 113a of the sidewall portion 113 at a bend point l₂, was 90°. Further, the region R₁ with mounting difficulty in the second main surface 112b was a region up to about 77 μm from the sidewall portion 113. In the cavity illustrated in FIG. 5, the width of the sidewall portion 113 was 100 μm, the width between the inner-side surfaces 113c facing each other across the recessed portion was 2000 μm, and the ratio of the width between the inner-side surfaces 113c facing each other across the recessed portion to the width of the sidewall portion 113 was 20.

### (Electronic Component Adhering Step)

In the electronic component adhering step, one or more electronic components 111 are adhered to the bottom surface (the second main surface 112b of the Si base layer 112) of the cavity. More specifically, first, the adhesive layer 115 (strictly speaking, a coating film of an adhesive) is formed on the second main surface 112b of the Si base layer 112. The coating film of the adhesive is formed on the second main surface 112b of the Si base layer 112. For the formation of the coating film, for example, spin coating, spray coating and mist CVD, inkjet, or die attach film (DAF) may be used. Strictly speaking, in a case of forming the coating film using a die attach film, a die attach film is attached in advance to the component electrode 111d side of the electronic component 111, and the electronic component 111 in this state is disposed on the second main surface 112b of the Si base layer 112. The adhesive layer 115 is formed in this manner. As a result, as illustrated in FIG. 6A, the cavity on which the coating film is formed is produced. It is preferable to perform coating while controlling the thickness of the coating film to have a range from the thickness of each component electrode 111d of the one or more electronic components 111 to 10 μm. The adhesive is, for example, a thermosetting resin. Such a thermosetting resin is, for example, a thermosetting resin containing a repeating unit derived from benzocyclobutene (BCB), and can be obtained by, for example, polymerizing 1,3-divinyl-1,1,3,3-tetramethyldisiloxane-bis-benzocyclobutene (DVS-bis-BCB). Examples of the commercially available product include “CYCLOTENE” manufactured by The Dow Chemical Company.

Next, as illustrated in FIG. 6B, the one or more electronic components 111 are disposed (mounted), while being faced down, on the bottom surface (the second main surface 112b of the Si base layer 112) of the cavity under an air atmosphere using, for example, an apparatus, such as a flip chip holder and a mounter, such that the component electrodes 111d and the insulating portions 111e are brought into contact with the bottom surface (the second main surface 112b of the Si base layer 112) of the cavity with the adhesive layer 115 (strictly speaking, the coating film of the adhesive) interposed between the bottom surface, and the component electrodes 111d and the insulating portions 111e.

Then, the coating film of the adhesive is cured to form the adhesive layer 115. Specifically, the coating film of the adhesive is heated with an oven to be cured, with the electronic components 111 disposed in the cavity. The oven may further include a pressure regulator (more specifically, a member having a depressurizing function and a pressurizing function). When the electronic components 111 are mounted on the bottom surface of the cavity, voids penetrate in the coating film of the adhesive in some cases. The oven with the pressure regulating member facilitates removal of the voids in the coating film. The one or more electronic components 111 are then adhered onto the second main surface 112b of the Si base layer 112.

### (Electronic Component Sealing Step)

In the electronic component sealing step, the one or more electronic components 111 are sealed with a resin to form the resin sealing portions 114. Specifically, in the electronic component sealing step, as illustrated in FIG. 6C, a dispenser is used to apply a liquid resin onto the cavity on which the one or more electronic components 111 are mounted, so as to fill the recessed portion and the sidewall portions 113. Thereafter, the applied liquid resin is molded using a compression molding machine. Thereafter, the liquid resin is cured using, for example, a hot air circulation oven. As a result, the resin sealing portions 114 are formed. Note that a tablet resin or a powder resin may be used in lieu of the liquid resin.

### (Resin Sealing Portion Thinning Step)

In the resin sealing portion thinning step, the resin sealing portions 114 are thinned. Specifically, in the resin sealing portion thinning step, as illustrated in FIG. 6D, the resin sealing portions 114 are ground and thinned using a Si wafer back grinder so as to expose the upper surfaces of the sidewall portions 113. In the resin sealing portion thinning step, the surfaces of the resin sealing portions 114 on the second surface 111b side of the electronic component 111 are ground. The amount of grinding is preferably as large as possible.

In FIG. 6D illustrating an example of the resin sealing portion thinning step, the resin sealing portions 114 of the electronic component layer 110 are ground; however, the one or more electronic components 111 may further be ground. Note that damage to the functional portions inside the electronic components 111 has to be avoided. The functional portions are, for example, a dielectric and an electrode in the case of a capacitor, and are wiring in the case of an inductor.

In the resin sealing portion thinning step, the CMP may be used for planarization after a back grinder is used. In the CMP, a target object is rotated on a polishing pad while slurry containing a chemical substance and abrasive grains is supplied, in a state in which the target object is fixed by the Si support 140. Chemical polishing with a chemical and mechanical polishing with a grindstone are simultaneously performed to planarize the target object.

### (Si Support Attaching Step)

In the Si support attaching step, as illustrated in FIG. 6E, the Si support 140 is attached to the resin sealing portions 114. Specifically, the Si wafer described in the cavity forming step to serve as the Si support 140 is additionally prepared. Then, the adhesive layer 150 (strictly speaking, the coating film of the adhesive) is formed on the Si support 140 by the method described in the electronic component adhering step. Thereafter, the resin sealing portions 114 are attached onto the Si support 140 such that the ground surfaces of the resin sealing portions 114 are in contact with the coating film, and are applied with pressure and are heated. As a result, the coating film of the adhesive is cured to form the adhesive layer 150, and the Si support 140 is disposed on the ground surfaces of the resin sealing portions 114 with the adhesive layer 150 interposed therebetween. The purpose of providing the Si support 140 is to prevent occurrence of adverse effects (more specifically, reduction in strength etc.) in the subsequent Si base layer thinning step that are caused by thinning the layers being in the manufacturing process more than conventional layers.

The Si support 140 can be thinned before being attached as necessary, from the viewpoint of improving processability. This is because the dielectric film is formed using an apparatus for semiconductor devices in the subsequent step. For example, when the thickness of the electronic component 111 is 150 μm, a Si wafer (φ300 mm, typical thickness of 775 μm) serving as the Si support 140 is thinned to about 625 μm. In attaching the Si support 140, the bonding strength of the adhesive layer 150 can be weakened in advance by ultraviolet light (UV light) irradiation, heating, or etching with a chemical solution in expectation of removal performed later.

### (Si Base Layer Thinning Step)

In the Si base layer thinning step, the Si base layer 112 is thinned. Specifically, in the Si base layer thinning step, as illustrated in FIG. 6F, the Si base layer 112 is ground in the same manner as in the resin sealing portion thinning step to thin the Si base layer 112 and planarize the ground surface. In the Si base layer thinning step, the Si base layer 112 is thinned while being (indirectly) supported by the Si support 140, and thus the Si base layer 112 can be thinned effectively. With this step, the composite component 1 that is excellent as an electronic component module and is made smaller in height and size can be manufactured by the method of manufacturing the composite component 1 according to the present embodiment. The amount of grinding is preferably as large as possible within the range capable of maintaining a certain strength by preventing the above adverse effects. Taking into account variations in the planarization of the ground surface, the thickness of the thinned Si base layer 112 is preferably 3 μm or more.

### (Dielectric Film Forming Step)

In the dielectric film forming step, the dielectric film 120a having a predetermined pattern is formed on the Si base layer 112, as illustrated in FIGS. 6G, 6H, and 6I.

FIGS. 6G to 6I are enlarged views of a portion corresponding to a portion C in FIG. 6F. The same applies to FIGS. 6J to 6M. Note that FIGS. 6G to 6M are views related mainly to the formation of the through-Si vias 117 and the redistribution layer 120, and thus, the figures are enlarged such that the through-Si vias 117, the redistribution layer 120, and the portions in which they are formed are largely occupied, for convenience sake.

Specifically, as illustrated in FIG. 6G, the dielectric film (thickness of 0.1 to 0.2 μm) 120a is formed on the entire surface of the Si base layer 112 by using a chemical vapor deposition (CVD) method, such as PECVD. One or more layers of the dielectric film 120a may be formed. For example, when the four layers of the dielectric film 120a are formed, the layers can be SiO₂: 0.25 μm/Si₃N₄: 0.1 μm/SiO₂: 0.25 μm/Si₃N₄0.1 μm in this order from the Si base layer 112 side. In the dielectric film forming step, the surface of the Si base layer 112 can be cleaned before the dielectric film 120a is formed. Examples of the cleaning include wet cleaning and oxygen plasma ashing.

Then, as illustrated in FIG. 6H and FIG. 6I, the dielectric film 120a is patterned using a photolithography method. A liquid resist is spin-coated to form a photoresist film 160 on the entire surface of the dielectric film 120a. The photoresist film 160 is exposed through a mask corresponding to a predetermined pattern. The exposed photoresist film 160 is developed. The dielectric film 120a of the photoresist film 160 is selectively removed using reactive ion etching (RIE). For example, when the above four layers of the dielectric film 120a are formed, two layers from the surface (on the side of the dielectric film 120a facing the Si base layer 112) of the dielectric film 120a are selectively removed. Thereafter, the photoresist film 160 is peeled off. As a result, the dielectric film 120a having the predetermined pattern is formed on the Si base layer 112. The dielectric film 120a also functions as an insulating film to electrically insulate the space between two of the through-Si vias 117 illustrated in FIG. 6L to be described later.

The first main surface 112a of the Si base layer 112 may further include a mark layer. The mark layer can be detected by an IR camera to perform alignment in a photolithography method.

### (Through-Hole Forming Step)

In the through-hole forming step, through-holes 112c and 115c are formed in the thinned Si base layer 112 and the adhesive layer 115 to expose a part of the surface of the component electrode 111d. Specifically, in the through-hole forming step, the photoresist film 160 is formed on the entire surface. A photoresist film 160 is exposed through a mask corresponding to a pattern of the through-Si via 117. The exposed photoresist film 160 is developed to form a photoresist film 160 having a predetermined pattern as illustrated in FIG. 6J. As illustrated in FIG. 6K, the Si base layer 112 and the adhesive layer 115 that are present from a cavity 160a of the photoresist film 160 in the Z direction, are selectively removed (etched). The etching is performed using, for example, RIE and laser irradiation. As a result, the through-holes 112c and 115c are formed, and each component electrode 111d (a part of the upper surface thereof) is exposed. The through-hole 115c of the adhesive layer 115 in the ZX section has a substantially elliptical shape. This is because the material constituting the adhesive layer 115 is more easily etched than the material constituting the Si base layer 112 is. Then, the substantially elliptical extending portion 117b is formed in the subsequent through-Si via forming step. After the through-holes 112c and 115c are formed, the photoresist film 160 is removed. The etching means is preferably RIE. Use of the RIE as the etching means improves the flatness of the upper surfaces of the component electrodes 111d to be exposed, so that favorable bonding to the through-Si vias 117 to be formed later can be established. This allows degradation of the electrical connectivity to be restrained.

### (Through-Si Via Forming Step)

In the through-Si via forming step, a through-Si via is formed in the through-holes. Specifically, in the through-hole forming step, as illustrated in FIG. 6L, the through-Si via 117 is formed in the through-holes 112c and 115c by electroplating. The through-Si via 117 is formed in the through-holes 112c and 115c by electrolytic plating (more specifically, electrolytic Cu plating) using a dual damascene method (more specifically, a Cu dual damascene method). The electronic component layer 110 is then formed. After the through-hole forming step and before the through-Si via forming step, a barrier layer and a seed layer may be formed on the inner walls of the through-holes 112c and 115c.

### (Redistribution Layer Forming Step)

In the redistribution layer forming step, the redistribution layer 120 is formed. Specifically, in the redistribution layer forming step, as illustrated in FIG. 6M, the dielectric film 120a having a predetermined pattern and the wiring 120b are formed by the above-described photolithography method and etching, and the redistribution layer 120 is formed. Since the electronic components 111 are mounted while being faced down, in the formation of the redistribution layer 120, wiring is formed using, for example, the dual damascene method and planarized by the CMP, and as a result, the redistribution layer 120 having a wiring width of submicron (1 μm or less) can be formed. On the contrary, when the electronic components are mounted while being faced up, wiring cannot be formed using the dual damascene method, and thus, a redistribution layer having a wiring width of single micron (1 μm or more) is formed.

FIG. 6M depicts the dielectric film 120a formed as in FIG. 6H and the wiring 120b formed as in FIG. 6L being incorporated in the redistribution layer 120. FIG. 6N illustrates the composite component 1 including FIG. 6M. FIG. 6M is the enlarged view of a portion C′ in FIG. 6N.

### (Operation Checking Step)

In the operation checking step, the operation (more specifically, continuity etc.) of the composite component 1 is checked.

### (Cutting Step)

In the cutting step, after the Si support 140 and the adhesive layer 150 are removed, the mother integrated body is cut with a dicing machine along the broken lines as illustrated in FIG. 6N using, for example, a blade dicer, a laser dicer, or a stealth dicer to singulate the mother integrated body. As a result, the composite component 1 is manufactured. In the removal of the Si support 140 and the adhesive layer 150, the adhesive strength of the adhesive layer 150 may be weakened by ultraviolet light (UV light) irradiation, heating, or etching with a chemical solution.

### Second Embodiment: Composite Component

A composite component according to a second embodiment is different from the composite component 1 according to the first embodiment in that the inner-side surface and the upper surface of the sidewall portion form an acute angle. In the composite component 1 according to the first embodiment, the inner-side surface 113c of the sidewall portion 113 and the upper surface 113a of the sidewall portion 113 form a right angle (90°). Hereinafter, this different configuration will be mainly described. In the second embodiment, the elements with the same reference signs as those of the first embodiment have the same configurations as those of the first embodiment, and thus, the description thereof will be basically omitted.

### [Configuration of Composite Component]

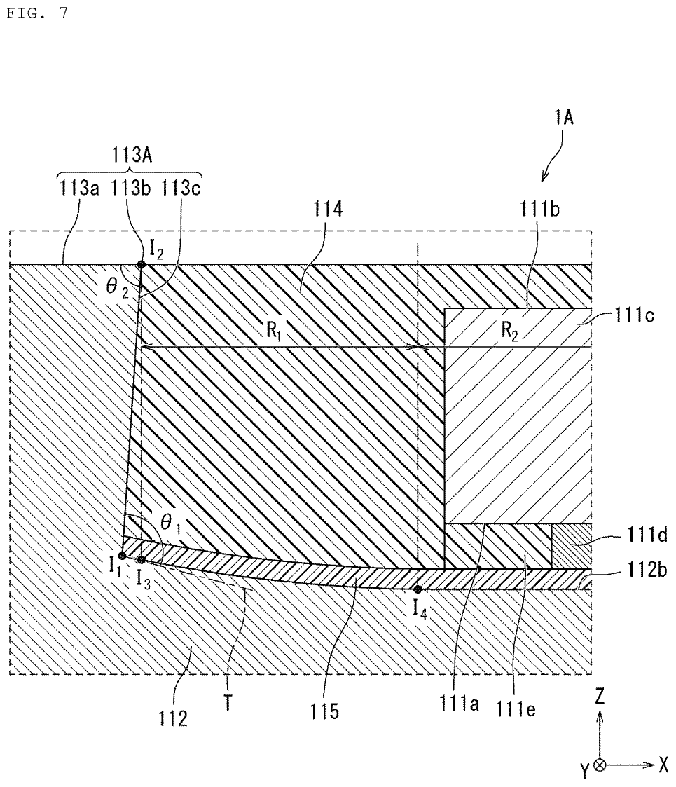

The configuration of the composite component according to the second embodiment will be described with reference to FIG. 7. FIG. 7 is a view schematically illustrating a section of a composite component 1A according to the second embodiment of the present disclosure. As illustrated in FIG. 7, an inner-side surface 113c of a sidewall portion 113A is inclined so as to form an acute angle (more specifically, an angle smaller than 90°) with an upper surface 113a of the sidewall portion 113 A in sectional view. When the inner-side surface 113c and the upper surface 113a of the sidewall portion 113A form an acute angle (at the bend point l₂), a resin sealing portion 114 is crimped by the sidewall portion 113A, so that falling off of the resin sealing portion 114 from the composite component 1A can be restrained from occurring due to internal stress (which may occur during the manufacture of the composite component 1A and the operation of the composite component 1A). Thus, the reliability of the composite component 1A is further enhanced.

In the present specification, an angle θ₂ formed by the inner-side surface 113c and the upper surface 113a at the bend point l₂ refers to an angle formed by the inner-side surface 113c being substantially linear and the upper surface 113a at the bend point l₂ (connection point 113b) connecting the inner-side surface 113c and the upper surface 113a, seen in the ZX section at a magnification of 700× (SEM image taken at a magnification of 700× using a scanning electron microscope (“FlexSEM” manufactured by Hitachi High-Tech Corporation)). The ZX section of the composite component 1A for determining an acute angle is formed by a similar method of forming the ZX section of the composite component 1 for determining an acute angle, except that the composite component 1 is changed to the composite component 1A.

The angle θ₂ formed by the inner-side surface 113c and the upper surface 113a at the bend point l₂ is less than 90°, preferably is 89° or less, and more preferably is 85° or less, from the viewpoint of restraining the occurrence of falling off of the resin sealing portion 114.

The acute angle θ₂ formed by the inner-side surface 113c and the upper surface 113a at the bend point I₂ can be achieved by controlling the acute angle by anisotropic etching time and isotropic etching time (more specifically, isotropic etching time longer than normal isotropic etching time, etc.), as described in a method of manufacturing the composite component 1A to be described later.

In the case that the angle θ₂ formed by the inner-side surface 113c and the upper surface 113a at the bend point l₂ is an acute angle, the region R₁ with mounting difficulty, in a second main surface 112b, for an electronic component 111, is a region from a point l₃ obtained by extending from the bend point l₂ (connection point 113b) of the upper surface 113a and the inner-side surface 113c perpendicularly to the second main surface 112b in the Z direction, to a point l₄ at which the curved line of the second main surface 112b is changed to the straight line.

### [Method of Manufacturing Composite Component]

An example of the method of manufacturing the composite component 1A according to the second embodiment will be described.

The method of manufacturing the composite component 1A is different from the method of manufacturing the composite component 1 only in the cavity forming step.

### (Cavity Forming Step)

In a cavity forming step, a cavity is formed under the same conditions as in the first embodiment except that the anisotropic etching time and the isotropic etching time are made longer. The angle θ₂ of the obtained cavity becomes an acute angle.

### Example

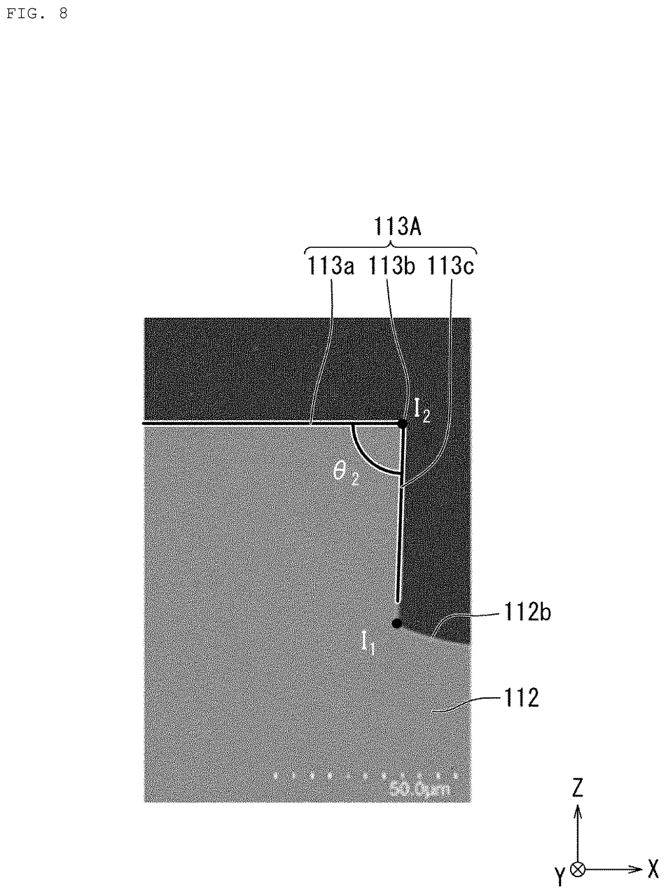

FIG. 8 is a sectional view illustrating the cavity (obtained by integrating the sidewall portion 113A and a Si base layer 112) formed in the cavity forming step of the method of manufacturing the composite component 1A. FIG. 8 is a scanning electron microscope image (SEM image taken at a magnification of 700× using a scanning electron microscope (“FlexSEM” manufactured by Hitachi High-Tech Corporation)) of a cut surface of the cavity. This cut surface included a point at which the diagonals of a bottom surface, of the cavity, having a substantially rectangular shape in plan view intersect, and was formed by being cut along a plane parallel to a surface to be cut in the cutting step. As illustrated in FIG. 8, the inner-side surface 113c of the sidewall portion 113A was inclined so as to form an acute angle (89°) with respect to the upper surface 113a.

### Other Embodiments

The present disclosure is not limited to the above-described embodiments, and design can be modified without departing from the spirit of the present disclosure. Further, the configurations of the first and second embodiments may be variously combined.

In the first and second embodiments, the composite component includes two electronic components of the same type, but is not limited thereto. For example, the composite component may include different types of electronic components, and may include one, or three or more electronic components. Further, the composite components may include different numbers of electronic components in the composite component layers. Thus, the number, types, and the like of the electronic components to be contained are less likely to be limited in circuit design, and the degree of freedom in design is high. A variety of circuit configurations become feasible, and the application range becomes wider.

In the first and second embodiments, the redistribution layer 120 includes the dielectric film 120a substantially including an inorganic material (inorganic insulating material) and the wiring (conductive wiring) 120b, but is not limited thereto. For example, the dielectric film may substantially include an organic material (organic insulating material). The dielectric film substantially including an organic material allows a composite component to be manufactured at a lower cost, as compared with the dielectric film substantially including an inorganic material. The line and space (L/S) of the redistribution layer 120 including the dielectric film substantially including an organic material is, for example, 10 μm/10 μm. The thickness of the dielectric film is, for example, 1 to 20 μm.

Examples of the organic insulating material include epoxy resin, silicone resin, polyester, polypropylene, polyimide, acrylonitrile-butadiene-styrene (ABS) resin, acrylonitrile-styrene (AS) resin, methacrylic resin, polyamide, fluororesin, liquid crystal polymer, polybutylene terephthalate, and polycarbonate. When the insulating material constituting the dielectric film is an organic insulating material, the dielectric film is formed without using a method, such as PECVD, for example, and thus, the cost can be reduced as compared with the composite component 1 according to the first embodiment.

Aspects of the composite component of the present disclosure are as follows.

<1> A composite component containing one or more electronic components. The composite component includes a Si base layer having a first main surface, and a second main surface facing the first main surface; a redistribution layer disposed on the first main surface; an electronic component disposed on the second main surface with an adhesive layer interposed between the electronic component and the second main surface; a through-Si via extending through the Si base layer and the adhesive layer to electrically connect the redistribution layer and the electronic component; sidewall portions surrounding the electronic component, and disposed to form a recessed portion together with the Si base layer; and a resin sealing portion sealing the electronic component.

<2> The composite component according to <1>, in which an inner-side surface of each of the sidewall portions and the second main surface of the Si base layer form an obtuse angle.

<3> The composite component according to <1> or <2>, in which a ratio of a width between the inner-side surfaces facing each other across the recessed portion to a width of each of the sidewall portions, is 10 to 1000.

<4> The composite component according to any one of <1> to <3>, in which the inner-side surface of each of the sidewall portions is inclined so as to form an acute angle with respect to an upper surface of each of the sidewall portions in sectional view.

<5> The composite component according to any one of <1> to <4>, in which the electronic component includes an electronic component body portion, and a component electrode disposed on the electronic component body portion, and the component electrode is electrically connected to the redistribution layer with only the through-Si via interposed between the component electrode and the redistribution layer.

The composite component according to the present disclosure can be used by being mounted on various electronic equipment.

What is claimed is:

1. A composite component including one or more electronic components, the composite component comprising:
a Si base layer having a first main surface, and a second main surface facing the first main surface;
a redistribution layer on the first main surface;
an electronic component on the second main surface with an adhesive layer interposed between the electronic component and the second main surface;
a through-Si via extending through the Si base layer and the adhesive layer to electrically connect the redistribution layer and the electronic component;
sidewall portions surrounding the electronic component, and configuring a recessed portion together with the Si base layer; and
a resin sealing portion sealing the electronic component.

2. The composite component according to claim 1, wherein
an inner-side surface of each of the sidewall portions and the second main surface of the Si base layer define an obtuse angle.

3. The composite component according to claim 1, wherein
a ratio of a width between an inner-side surfaces facing each other across the recessed portion to a width of each of the sidewall portions, is 10 to 1000.

4. The composite component according to claim 1, wherein
an inner-side surface of each of the sidewall portions is inclined to define an acute angle with respect to an upper surface of each of the sidewall portions in sectional view.

5. The composite component according to claim 1, wherein
the electronic component includes an electronic component body portion, and a component electrode on the electronic component body portion, and
the component electrode is electrically connected to the redistribution layer with only the through-Si via interposed between the component electrode and the redistribution layer.

6. The composite component according to claim 2, wherein
a ratio of a width between the inner-side surfaces facing each other across the recessed portion to a width of each of the sidewall portions, is 10 to 1000.

7. The composite component according to claim 2, wherein
the inner-side surface of each of the sidewall portions is inclined to define an acute angle with respect to an upper surface of each of the sidewall portions in sectional view.

8. The composite component according to claim 3, wherein
the inner-side surface of each of the sidewall portions is inclined to define an acute angle with respect to an upper surface of each of the sidewall portions in sectional view.

9. The composite component according to claim 6, wherein
the inner-side surface of each of the sidewall portions is inclined to define an acute angle with respect to an upper surface of each of the sidewall portions in sectional view.

10. The composite component according to claim 2, wherein
the electronic component includes an electronic component body portion, and a component electrode on the electronic component body portion, and
the component electrode is electrically connected to the redistribution layer with only the through-Si via interposed between the component electrode and the redistribution layer.

11. The composite component according to claim 3, wherein
the electronic component includes an electronic component body portion, and a component electrode on the electronic component body portion, and
the component electrode is electrically connected to the redistribution layer with only the through-Si via interposed between the component electrode and the redistribution layer.

12. The composite component according to claim 4, wherein
the electronic component includes an electronic component body portion, and a component electrode on the electronic component body portion, and
the component electrode is electrically connected to the redistribution layer with only the through-Si via interposed between the component electrode and the redistribution layer.

13. The composite component according to claim 6, wherein
the electronic component includes an electronic component body portion, and a component electrode on the electronic component body portion, and
the component electrode is electrically connected to the redistribution layer with only the through-Si via interposed between the component electrode and the redistribution layer.

14. The composite component according to claim 7, wherein
the electronic component includes an electronic component body portion, and a component electrode on the electronic component body portion, and
the component electrode is electrically connected to the redistribution layer with only the through-Si via interposed between the component electrode and the redistribution layer.

15. The composite component according to claim 8, wherein
the electronic component includes an electronic component body portion, and a component electrode on the electronic component body portion, and
the component electrode is electrically connected to the redistribution layer with only the through-Si via interposed between the component electrode and the redistribution layer.

16. The composite component according to claim 9, wherein
the electronic component includes an electronic component body portion, and a component electrode on the electronic component body portion, and
the component electrode is electrically connected to the redistribution layer with only the through-Si via interposed between the component electrode and the redistribution layer.
